(19) United States
(12) Patent Application Publication
(10) Pub. No.: US 2026/0106487 A1
(43) Pub. Date: Apr. 16, 2026

(54) UNINTERRUPTIBLE POWER SUPPLY DEVICE

(71) Applicants: TMEIC Corporation, Tokyo (JP); Mitsubishi Electric Corporation, Tokyo (JP)

(72) Inventors: Nobuyuki MOMOCHI, Chuo-ku (JP); Hiroshi MASUNAGA, Chuo-ku (JP); Seiji HIRAI, Chiyoda-ku (JP); Hiroto NISHIGUCHI, Chiyoda-ku (JP)

(73) Assignees: TMEIC Corporation, Tokyo (JP); Mitsubishi Electric Corporation, Tokyo (JP)

(21) Appl. No.: 19/112,793

(22) PCT Filed: Aug. 30, 2023
(86) PCT No.: PCT/JP2023/031459

§ 371 Date: Mar. 18, 2025

(51) Int. Cl. H02J 9/06; G01R 31/36; G01R 31/382; H02J 7/00; H02J 7/02; H02J 7/80

(52) U.S. Cl. CPC H02J 9/062; G01R 31/3646; G01R 31/382; H02J 7/02; H02J 7/80; H02J 7/855

(57) ABSTRACT

An uninterruptible power supply device has a normal mode of supplying a load with electric power supplied from an AC power supply, a backup mode of supplying the load with electric power stored in a storage battery during a power failure, and a deterioration diagnosis mode of diagnosing a deteriorated state of the storage battery. A controller periodically shifts to the deterioration diagnosis mode during execution of the normal mode. During execution of the deterioration diagnosis mode, the controller stops charging of the storage battery by stopping an operation of the power converter. The controller measures a voltage of the storage battery at a first timing after a lapse of a first time period from stopping charging of the storage battery, and diagnoses the deteriorated state of the storage battery based on a measured value of the voltage of the storage battery at the first timing.

### TECHNICAL FIELD

The present disclosure relates to an uninterruptible power supply device, and more particularly, to a technique of diagnosing deterioration of a storage battery used in the uninterruptible power supply device.

### BACKGROUND ART

For example, Japanese Patent Laying-Open No. 2008-259296 (PTL 1) discloses an uninterruptible power supply device including an uninterruptible power supply device body, a plurality of storage batteries, and automatic storage battery deterioration diagnosis means. The uninterruptible power supply device body includes a converter that converts electric power input from an alternate-current (AC) power supply into direct-current (DC) power and an inverter that converts the DC power output from the converter into AC power and outputs the AC power to a load. A plurality of storage batteries are connected in series in a DC power unit between the converter and the inverter to supply electric power to the load in the event of an abnormality of the AC power supply. The automatic storage battery deterioration diagnosis means detects an abnormality in the plurality of storage batteries as a whole by test charge of the plurality of storage batteries during operation of the uninterruptible power supply device.

In the configuration described above, the floating charge voltage of the storage batteries gradually decreases during execution of test discharge of the plurality of storage batteries. However, as the storage batteries become deteriorated, the decrease in floating charge voltage during discharge becomes more pronounced. The automatic storage battery deterioration diagnosis means determines that an abnormality has occurred in the plurality of storage batteries as a whole when the floating charge voltage drops to an abnormality determination voltage during test discharge.

### CITATION LIST

### Patent Literature

PTL 1: Japanese Patent Laying-Open No. 2008-259296

### SUMMARY OF INVENTION

### Technical Problem

The uninterruptible power supply device described in PTL 1 diagnoses a deteriorated state of the plurality of storage batteries by test-discharging the storage batteries using the automatic storage battery deterioration diagnosis means while supplying electric power to the load during normal operation in which electric power is supplied from the AC power supply. Thus, during the test discharge, the electric power input from the AC power supply is supplied to the load through the uninterruptible power supply device body, and the electric power discharged from the plurality of storage batteries is supplied to the load. Consequently, when the uninterruptible power supply device is operated under light load, the current output from the uninterruptible power supply device to the load becomes smaller, making it difficult to pass a constant current for test discharge to the plurality of storage batteries. As a result, the automatic storage battery deterioration diagnosis means may not be able to diagnose the deteriorated state of the plurality of storage batteries under light load under which the load current is small.

In addition, in order to improve the power feed reliability of the uninterruptible power supply device in the event of an abnormality of the AC power supply, it is required to enable more accurate diagnosis of the deteriorated state of the storage battery.

The present disclosure has been made in view of the above problem. The present disclosure has an object to provide an uninterruptible power supply device capable of accurately diagnosing a deteriorated state of a storage battery, regardless of the magnitude of a load.

### Solution to Problem

An uninterruptible power supply device according to the present disclosure has a normal mode of supplying a load with electric power supplied from an AC power supply, a backup mode of supplying the load with electric power stored in a storage battery during a power failure of the AC power supply, and a deterioration diagnosis mode of diagnosing a deteriorated state of the storage battery. The uninterruptible power supply device includes a power converter and a controller. The power converter performs floating charge of the storage battery with the electric power supplied from the AC power supply in the normal mode, and discharges the storage battery in the backup mode. The controller periodically shifts to the deterioration diagnosis mode during execution of the normal mode. During execution of the deterioration diagnosis mode, the controller stops charging of the storage battery by stopping an operation of the power converter. The controller measures a voltage of the storage battery at a first timing after a lapse of a first time period from stopping charging of the storage battery, and diagnoses a deteriorated state of the storage battery based on a measured value of the voltage of the storage battery at the first timing.

### Advantageous Effects of Invention

According to the present disclosure, the uninterruptible power supply device can be provided that can accurately diagnose the deteriorated state of the storage battery regardless of the magnitude of the load.

### BRIEF DESCRIPTION OF DRAWINGS

FIG. 1 is a circuit block diagram showing a configuration of an uninterruptible power supply device according to Embodiment 1.

FIG. 2 is a block diagram showing an example hardware configuration of a controller.

FIG. 3 is a block diagram showing the main part of the controller.

FIG. 4 illustrates operation modes of the uninterruptible power supply device.

FIG. 5 is a block diagram showing portions of a control circuit which are related to control of a converter, an inverter, and a bidirectional chopper.

FIG. 6 is a diagram for illustrating a battery deterioration diagnosis process in a deterioration diagnosis unit.

FIG. 7 shows an example relationship between a time period of use of a battery and a DC resistance.

FIG. 8 is a flowchart showing a flow of the battery deterioration diagnosis process according to Embodiment 1.

FIG. 9 is a diagram for illustrating a deterioration diagnosis process in a deterioration diagnosis unit according to Embodiment 2.

FIG. 10 is a flowchart showing a flow of the battery deterioration diagnosis process according to Embodiment 2.

FIG. 11 is a flowchart showing a flow of a battery deterioration diagnosis process according to Embodiment 3.

FIG. 12 is a flowchart showing a flow of the battery deterioration diagnosis process according to Embodiment 3.

FIG. 13 is a circuit block diagram showing a configuration of an uninterruptible power supply device according to Embodiment 4.

### DESCRIPTION OF EMBODIMENTS

Embodiments of the present disclosure will be described in detail with reference to the drawings. The same or corresponding parts in the figures have the same reference characters allotted, and description thereof will not be repeated.

### Embodiment 1

### <Configuration of Uninterruptible Power Supply Device>

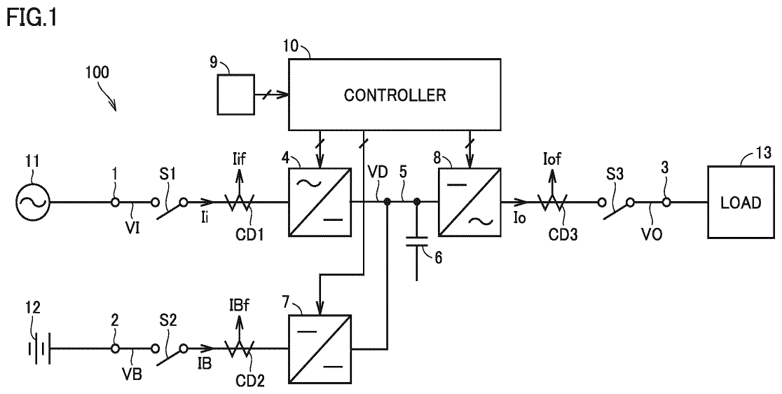

FIG. 1 is a circuit block diagram showing a configuration of an uninterruptible power supply device according to Embodiment 1.

As shown in FIG. 1, an uninterruptible power supply device 100 according to Embodiment 1 includes an input terminal 1, a DC terminal 2, an output terminal 3, switches S1 to S3, a converter 4, current detectors CD1 to CD3, a DC line 5, a capacitor 6, a bidirectional chopper 7, an inverter 8, an operation unit 9, and a controller 10. Uninterruptible power supply device 100 supplies three-phase AC power to a load 13, but for simplicity of the drawing and description, only the portions related to one phase are shown in FIG. 1.

Input terminal 1 receives AC power of a predetermined frequency (e.g., commercial frequency) from an AC power supply 11. AC power supply 11 may be a commercial AC power supply or a generator.

DC terminal 2 is connected to a battery 12. Battery 12 stores DC power. Battery 12 is a secondary battery, such as a lithium-ion battery or a lead-acid battery. Battery 12 corresponds to an embodiment of the “storage battery”.

Output terminal 3 is connected to load 13. Load 13 is driven by AC power of a predetermined frequency (e.g., commercial frequency) supplied from uninterruptible power supply device 100.

Switch S1 is connected between input terminal 1 and an AC node of converter 4, and is controlled by controller 10. When AC power is normally supplied from AC power supply 11 (during normal operation of AC power supply 11), switch S1 is turned on, and AC power is supplied from AC power supply 11 to converter 4 through switch S1. When AC power is not normally supplied from AC power supply 11 (during a power failure of AC power supply 11), switch S1 is turned off, and AC power supply 11 and converter 4 are disconnected from each other.

An instantaneous value of an AC input voltage VI supplied from AC power supply 11 is detected by controller 10. Based on the instantaneous value of AC input voltage VI, controller 10 determines whether an AC voltage is normally supplied from AC power supply 11. Current detector CD1 detects an AC input current Ii flowing between AC power supply 11 and converter 4, and provides a signal Iif, which indicates a detected value thereof, to controller 10.

Converter 4 is controlled by controller 10 to convert the AC power from AC power supply 11 into DC power and output the DC power to DC line 5 during normal operation of AC power supply 11. Converter 4 is a well-known one that includes a plurality of sets of insulated gate bipolar transistors (IGBTs) and diodes.

Capacitor 6 is connected to DC line 5 to smooth and stabilize a DC voltage VD of DC line 5. An instantaneous value of DC voltage VD of DC line 5 is detected by controller 10.

During normal operation of AC power supply 11, controller 10 controls converter 4 such that DC voltage VD of DC line 5 becomes equal to a reference DC voltage VDR. During a power failure of AC power supply 11, controller 10 stops an operation of converter 4.

DC line 5 is connected to DC terminal 2 via bidirectional chopper 7 and switch S2. Switch S2 is controlled by controller 10. Switch S2 is turned on when uninterruptible power supply device 100 is used. Switch S2 is turned off during maintenance of battery 12 and bidirectional chopper 7.

An instantaneous value of a voltage VB between the terminals (hereinafter also denoted as “battery voltage”) of battery 12 is detected by controller 10. Current detector CD2 detects a DC current IB flowing between battery 12 and bidirectional chopper 7, and provides a signal IBf, which indicates a detected value thereof, to controller 10.

Bidirectional chopper 7 is controlled by controller 10 to transmit and receive DC power between DC line 5 and battery 12. Bidirectional chopper 7 is a well-known one that includes a plurality of sets of IGBTs and diodes, and a reactor.

During normal operation of AC power supply 11, controller 10 controls bidirectional chopper 7 such that battery voltage VB becomes equal to reference DC voltage VBR. During a power failure of AC power supply 11, controller 10 controls bidirectional chopper 7 such that DC voltage VD of DC line 5 becomes equal to reference DC voltage VDR. Bidirectional chopper 7 corresponds to an embodiment of the “power converter”.

DC line 5 is connected to a DC node of inverter 8, and an AC node of inverter 8 is connected to output terminal 3 via switch S3. Switch S3 is controlled by controller 10. Switch S3 is turned on when uninterruptible power supply device 100 is used. Switch S3 is turned off during maintenance of inverter 8.

Current detector CD3 detects an AC output current Io of inverter 8 and provides a signal Iof, which indicates a detected value thereof, to controller 10. AC output current Io corresponds to a load current flowing from uninterruptible power supply device 100 to load 13. An instantaneous value of an AC output voltage VO applied to load 13 is detected by controller 10.

Inverter 8 is controlled by controller 10, and converts the DC power supplied from converter 4 and bidirectional chopper 7 through DC line 5 into AC power of a predetermined frequency (e.g., commercial frequency) and supplies the AC power to load 13. Inverter 8 is a well-known one that includes a plurality of sets of IGBTs and diodes.

During normal operation of AC power supply 11, inverter 8 converts the DC power supplied from converter 4 or bidirectional chopper 7 into AC power and supplies the AC power to load 13. At this time, controller 10 controls inverter 8 such that AC output voltage VO becomes equal to a sinusoidal reference AC voltage VOR.

Operation unit 9 includes a plurality of buttons, a plurality of switches, and an image display unit. The user of uninterruptible power supply device 100 can operate operation unit 9 to turn on and off uninterruptible power supply device 100 and operate uninterruptible power supply device 100 automatically or manually. Operation unit 9 outputs a signal and information indicating what has been operated by the user to controller 10.

Controller 10 controls switches S1 to S3, converter 4, bidirectional chopper 7, and inverter 8 based on the signal from operation unit 9, AC input voltage VI, AC output voltage VO, DC voltage VD, battery voltage VB, AC input current Ii, battery current IB, and AC output current Io.

### <Hardware Configuration of Controller>

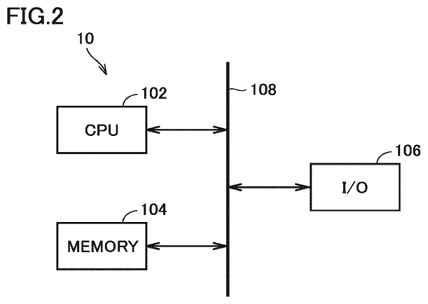

FIG. 2 is a block diagram showing an example hardware configuration of controller 10. Typically, controller 10 can be configured of a microcomputer with a predetermined program stored in advance.

In the example shown in FIG. 2, controller 10 includes a central processing unit (CPU) 102, a memory 104, and an input/output (I/O) circuit 106. CPU 102, memory 104, and I/O circuit 106 can exchange data with each other via a bus 108. Memory 104 has a partial area with programs stored, and various functions, which will be described later, can be implemented as CPU 102 executes the programs. I/O circuit 106 inputs and outputs signals and data to and from the outside of controller 10.

Alternatively, unlike the example shown in FIG. 2, at least part of controller 10 can be configured using a circuit such as a field programmable gate array (FPGA) or an application specific integrated circuit (ASIC). Also, at least part of controller 10 can be configured using an analog circuit.

### <Functional Configuration of Controller>

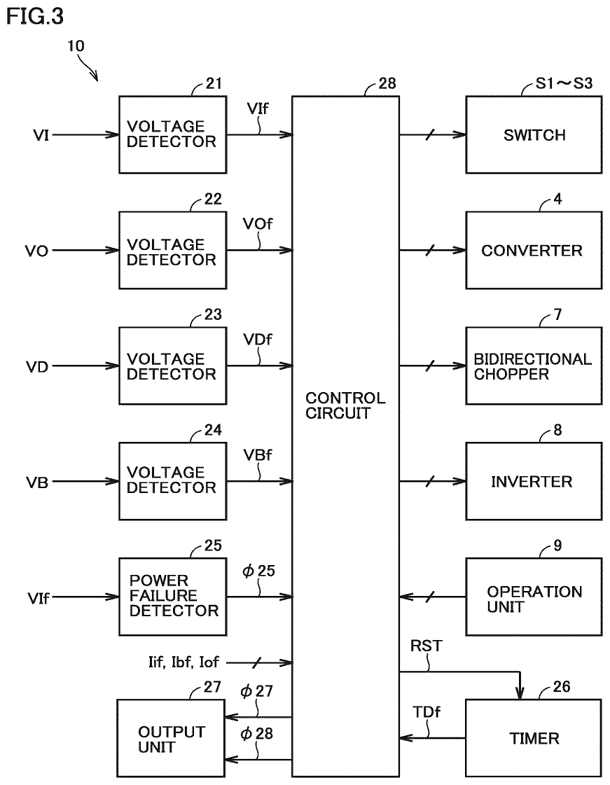

FIG. 3 is a block diagram showing the main part of controller 10. As shown in FIG. 3, controller 10 includes voltage detectors 21 to 24, a power failure detector 25, a timer 26, an output unit 27, and a control circuit 28.

Voltage detector 21 detects an instantaneous value of AC input voltage VI supplied from AC power supply 11 and outputs a signal VIf, which indicates a detected value thereof, to power failure detector 25 and control circuit 28. Voltage detector 22 detects an instantaneous value of AC output voltage VO applied to load 13 and outputs a signal VOf, which indicates a detected value thereof, to control circuit 28.

Voltage detector 23 detects an instantaneous value of DC voltage VD of DC line 5 and outputs a signal VDf, which indicates a detected value thereof, to control circuit 28. Voltage detector 24 detects an instantaneous value of battery voltage VB and outputs a signal VBf, which indicates a detected value thereof, to control circuit 28. Signals Iif, IBf, Iof output from current detectors CD1 to CD3 (FIG. 1) are provided to control circuit 28.

Power failure detector 25 detects whether a power failure has occurred in AC power supply 11 based on signal VIf output from voltage detector 21, and outputs a power failure detection signal φ25, which indicates a detection result thereof, to control circuit 28. During normal operation of AC power supply 11, power failure detection signal φ25 is set to an “H” level, which is a deactivation level. When a power failure has occurred in AC power supply 11, power failure detection signal φ25 is set to an “I.” level, which is the activation level.

For example, when AC input voltage VI is higher than a lower limit, power failure detector 25 determines that AC power supply 11 is normal, and sets power failure detection signal φ25 to the “H” level that is the deactivation level. When AC input voltage VI is lower than the lower limit, power failure detector 25 determines that a power failure has occurred in AC power supply 11, and sets power failure detection signal 25 to the “L” level that is the activation level.

Timer 26 is reset when a reset signal RST from control circuit 28 has been set at the “H” level that is the deactivation level for a predetermined time period, measures a time period TD that has elapsed since the reset, and outputs a signal TDf, which indicates measured time period TD, to control circuit 28.

Control circuit 28 controls the entire uninterruptible power supply device 100 based on signals VIf, VOf, VDf, VBf output from voltage detectors 21 to 24, signals Iif, IBf, Iof output from current detectors CD1 to CD3, signal φ25, and the signal from operation unit 9.

When AC power supply 11 is normal, control circuit 28 periodically diagnoses the deteriorated state of battery 12 while supplying AC power to load 13. Based on a diagnosis result, control circuit 28 outputs a state signal φ28, which indicates a deteriorated state of battery 12, to output unit 27. State signal φ28 can include information on a direct current resistance (DCR) of battery 12 obtained from the deterioration diagnosis.

Based on the diagnosis result, control circuit 28 determines whether battery 12 has deteriorated, and outputs a deterioration detection signal 27, which indicates a determination result, to output unit 27. When it is determined that battery 12 has not deteriorated, deterioration detection signal φ27 is set to the “L” level that is the deactivation level. When it is determined that battery 12 has deteriorated, deterioration detection signal 27 is set to the “H” level that is the activation level. The deterioration diagnosis of battery 12 will be described later.

Output unit 27 presents an image or the like representing the deteriorated state of battery 12 to the user of uninterruptible power supply device 100 based on state signal φ28. Output unit 27 also notifies the user of uninterruptible power supply device 100 that battery 12 has deteriorated, using sound, light, an image, or the like when deterioration detection signal φ27 is set to the “H” level that is the activation level. The image display unit of operation unit 9 can be used for output unit 27.

Alternatively, an external device (e.g., a server) connected in communication with uninterruptible power supply device 100 can be used for output unit 27. The external device is configured to receive state signal 28 and deterioration detection signal ¢27 from uninterruptible power supply device 100 via a communication network such as the Internet and, based on the received signal, present information on the deteriorated state of battery 12 to the user. This allows the user of uninterruptible power supply device 100 to remotely monitor the deteriorated state of battery 12.

### <Operation Modes of Uninterruptible Power Supply Device>

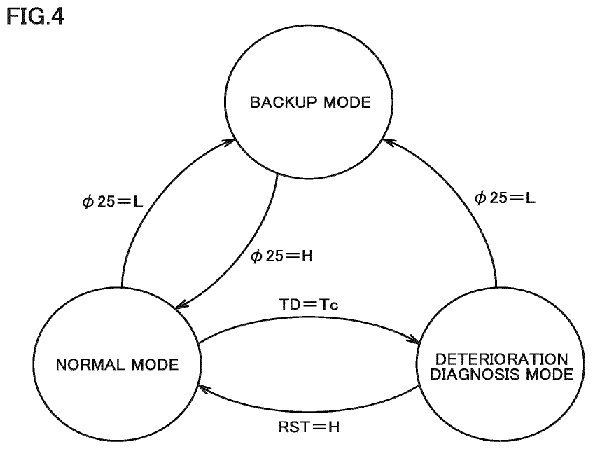

FIG. 4 illustrates operation modes of uninterruptible power supply device 100. As shown in FIG. 4, uninterruptible power supply device 100 has a normal mode, a backup mode, and a deterioration diagnosis mode. Control circuit 28 selectively performs the normal mode, the backup mode, and the deterioration diagnosis mode based on power failure detection signal φ25, signal TDf output from timer 26, and reset signal RST.

### (Normal Mode)

When AC power supply 11 is normal (φ25=H), control circuit 28 performs the normal mode. In the normal mode, control circuit 28 turns on switches S1 to S3. Control circuit 28 also controls converter 4 based on signals VIf, VDf, Iif such that DC voltage VD of DC line 5 becomes equal to reference DC voltage VDR. Further, control circuit 28 controls bidirectional chopper 7 such that battery voltage VB becomes equal to reference DC voltage VBR based on signals VBf, Ibf.

Control circuit 28 also controls inverter 8 based on signals VOf, Iof such that AC output voltage VO of inverter 8 becomes equal to sinusoidal reference AC voltage VOR. In this case, a load current is supplied from inverter 8 to load 13, so that load 13 is operated.

### (Backup Mode)

When a power failure occurs in AC power supply 11 (φ25=L), control circuit 28 performs the backup mode. In the backup mode, control circuit 28 turns off switch S1 to stop the operation of converter 4. Control circuit 28 also controls bidirectional chopper 7 based on signals VBf, Ibf such that DC voltage VD of DC line 5 becomes equal to reference DC voltage VDR. Further, control circuit 28 controls inverter 8 based on signals VOf, Iof such that AC output voltage VO of inverter 8 becomes equal to sinusoidal reference AC voltage VOR. Therefore, even when a power failure occurs in AC power supply 11, the operation of load 13 can be continued during the period in which DC power is stored in battery 12.

When AC power supply 11 is restored from the power failure state to be normal (φ25=H), control circuit 28 shifts from the backup mode to the normal mode. Control circuit 28 turns on switch S1, starts an operation of converter 4, controls converter 4 such that DC voltage VD of DC line 5 becomes equal to reference DC voltage VD, and controls bidirectional chopper 7 such that battery voltage VB becomes equal to reference DC voltage VBR. Control circuit 28 also controls inverter 8 such that AC output voltage VO of inverter 8 becomes equal to sinusoidal reference AC voltage VOR.

### (Deterioration Diagnosis Mode)

When time period TD indicated by signal TDf output from timer 26 exceeds a predetermined time period Tc during execution of the normal mode, control circuit 28 performs the deterioration diagnosis mode. Predetermined time period Tc is a cycle for executing the deterioration diagnosis mode during execution of the normal mode.

In the deterioration diagnosis mode, control circuit 28 controls converter 4 based on signals VIf, VDf, Iif such that DC voltage VD of DC line 5 becomes equal to reference DC voltage VDR. Control circuit 28 also controls inverter 8 based on signals VOf, Iof such that AC output voltage VO of inverter 8 becomes equal to sinusoidal reference AC voltage VOR.

Then, control circuit 28 diagnoses the deteriorated state of battery 12 while supplying AC power from inverter 8 to load 13. At this time, control circuit 28 controls an operation of bidirectional chopper 7 based on signal TDf output from timer 26. The control of bidirectional chopper 7 will be described later. Control circuit 28 diagnoses the deteriorated state of battery 12 based on battery voltage VB indicated by signal VBf, and outputs state signal φ28 indicating the deteriorated state to output unit 27. Control circuit 28 also determines whether battery 12 has deteriorated based on battery voltage VB. When determining that battery 12 has deteriorated, control circuit 28 sets deterioration detection signal φ27 to the “H” level that is the activation level. When determining that battery 12 has not deteriorated, control circuit 28 sets deterioration detection signal 427 to the “L” level that is the deactivation level.

When the execution of the deterioration diagnosis mode is completed, control circuit 28 sets reset signal RST to the “H” level that is the activation level for a predetermined time period to reset timer 26, and performs the normal mode again.

When a power failure occurs in AC power supply 11 during execution of the deterioration diagnosis mode (φ25=L), control circuit 28 performs the backup mode.

In this case, control circuit 28 stops an operation of converter 4 and controls bidirectional chopper 7 such that DC voltage VD of DC line 5 becomes equal to reference DC voltage VDR. In response to the interruption of execution of the deterioration diagnosis mode, control circuit 28 sets reset signal RST to the “H” level that is the activation level for a predetermined time period to reset timer 26.

### <Functional Configuration of Control Circuit>

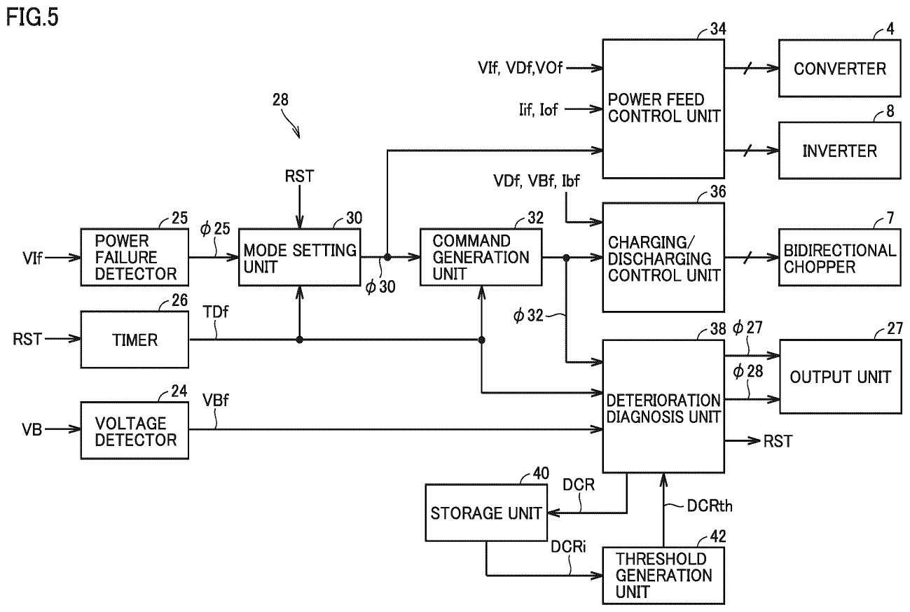

FIG. 5 is a block diagram showing portions of control circuit 28 which are related to control of converter 4, inverter 8, and bidirectional chopper 7. As shown in FIG. 5, control circuit 28 includes a mode setting unit 30, a command generation unit 32, a power feed control unit 34, a charging/discharging control unit 36, a deterioration diagnosis unit 38, a storage unit 40, and a threshold generation unit 42.

Mode setting unit 30 sets an operation mode of uninterruptible power supply device 100 based on signal φ25 output from power failure detector 25, signal TDf output from timer 26, and reset signal RST provided by deterioration diagnosis unit 38. Specifically, when power failure detection signal φ25 is at the “H” level and measured time period TD of timer 26 is less than predetermined time period Tc, mode setting unit 30 sets the operation mode to the normal mode. When power failure detection signal φ25 is at the “H” level and measured time period TD of timer 26 exceeds predetermined time period Tc, mode setting unit 30 sets the operation mode to the deterioration diagnosis mode. When power failure detection signal φ25 is at the “L” level, mode setting unit 30 sets the operation mode to the backup mode. Mode setting unit 30 outputs a signal φ30, which indicates the set operation mode, to power feed control unit 34 and command generation unit 32.

Power feed control unit 34 controls converter 4 and inverter 8 based on signal φ30 output from mode setting unit 30, signals VIf, VDf, VOf output from voltage detectors 21 to 23, and signals Iif, Iof output from current detectors CD1, CD2.

Specifically, when the operation mode indicated by signal φ30 is the normal mode or the deterioration diagnosis mode, power feed control unit 34 controls converter 4 based on signals VIf, VDf, Iif such that DC voltage VD of DC line 5 becomes equal to reference DC voltage VDR. Power feed control unit 34 also controls inverter 8 based on signals VOf, Iof such that AC output voltage VO of inverter 8 becomes equal to sinusoidal reference AC voltage VOR.

When the operation mode indicated by signal φ30 is the backup mode, power feed control unit 34 stops the operation of converter 4 and controls inverter 8 based on signals VOf, Iof such that AC output voltage VO of inverter 8 becomes equal to sinusoidal reference AC voltage VOR.

Command generation unit 32 generates a charging command to instruct execution/stop of charging of battery 12 and a discharging command to instruct execution/stop of discharging of battery 12, based on signal φ30 output from mode setting unit 30 and signal TDf output from timer 26. The charging command is set to the “H” level that is the activation level when the execution of charging of battery 12 is instructed, and the charging command is set to the “I,” level that is the deactivation level when stop of charging is instructed. The discharging command is set to the “H” level that is the activation level when the execution of discharging battery 12 is instructed, and the discharging command is set to the level “L” that is the deactivation level when stop of discharging is instructed.

When the operation mode indicated by signal φ30 is the normal mode, the charging command is set to the “H” level and the discharging command is set to the “L” level. When the operation mode indicated by signal φ30 is the backup mode, the charging command is set to the “L” level and the discharging command is set to the “H” level.

When the operation mode indicated by signal φ30 is the deterioration diagnosis mode, the charging command is set to the “L” level and the discharging command is set to the “L” level. However, the discharging command is set to the “H” level for a predetermined time period T2 based on signal TDf output from timer 26 during execution of the deterioration diagnosis mode. Command generation unit 32 outputs a signal φ32, which indicates the generated charging command and discharging command, to charging/discharging control unit 36 and deterioration diagnosis unit 38.

Charging/discharging control unit 36 controls bidirectional chopper 7 based on signal φ32 output from command generation unit 32, signals VDf, VBf output from voltage detectors 23, 24, and signal IBf output from current detector CD2.

Specifically, when the charging command indicated by signal φ32 is at the “H” level and the discharging command is at the “I.” level, charging/discharging control unit 36 controls bidirectional chopper 7 such that battery voltage VB becomes equal to reference DC voltage VBR. When the charging command indicated by signal φ32 is at the “L” level and the discharging command is at the “H” level, charging/discharging control unit 36 controls bidirectional chopper 7 such that DC voltage VD of DC line 5 becomes equal to reference DC voltage VDR. When both the charging command and the discharging command indicated by signal φ32 are at the “L” level, charging/discharging control unit 36 stops the operation of bidirectional chopper 7.

Deterioration diagnosis unit 38 diagnoses the deteriorated state of battery 12 based signal φ32 output from command generator unit 32, signal TDf output from timer 26, and signal VBf output from voltage detector 24.

### <Battery Deterioration Diagnosis Process>

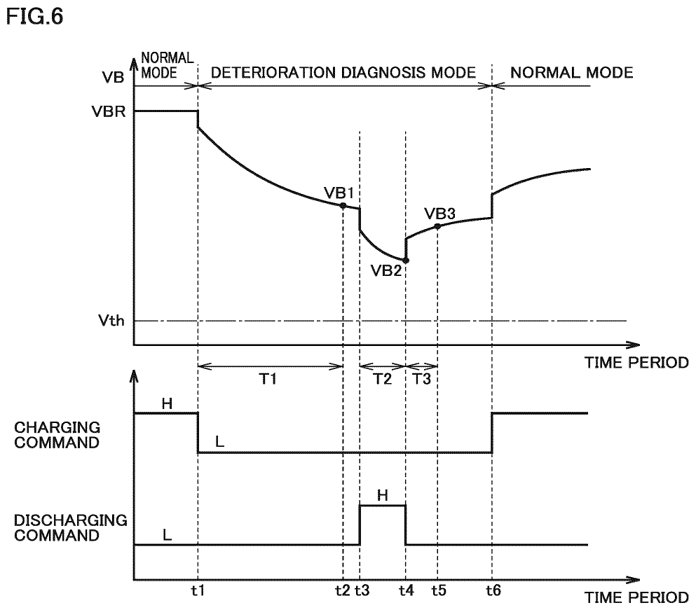

FIG. 6 is a diagram for illustrating the deterioration diagnosis process for battery 12 in deterioration diagnosis unit 38. FIG. 6 shows the waveform of battery voltage VB indicated by signal VBf output from voltage detector 24, and the waveforms of the charging command and the discharging command generated by command generation unit 32.

Referring to FIG. 6, at a time t1, when measured time period TD of timer 26 exceeds predetermined time period Tc, uninterruptible power supply device 100 shifts from the normal mode to the deterioration diagnosis mode.

During execution of the normal mode before time t1, the charging command is set to the “H” level and the discharging command is set to the “L” level. In response to the charging command at the “H” level, charging/discharging control unit 36 controls bidirectional chopper 7 such that battery voltage VB becomes equal to reference DC voltage VBR. As a result, floating charge of battery 12 is performed, and battery voltage VB at time t1 is equal to reference DC voltage VBR.

In response to the shift to the deterioration diagnosis mode at time t1, the charging command is set to the “L” level. In response to the charging command at the “L” level, charging/discharging control unit 36 stops charging battery 12 by stopping the operation of bidirectional chopper 7.

Due to the stop of charging of battery 12, battery voltage VB gradually drops after time t1. This drop in battery voltage VB is caused by the internal resistance of battery 12. Specifically, battery voltage VB drops abruptly immediately after the stop of charging. This voltage drop is due to a voltage drop (IR drop) caused by the current during charging and the internal resistance of battery 12. Also after the voltage drop caused by the IR drop, battery voltage VB drops gradually. This behavior of battery voltage VB after the stop of charging is also called a relaxation characteristic or a transient characteristic.

The IR drop is mainly due to an ohmic component contained in the internal resistance of battery 12. It is considered that the gradual voltage drop after the IR drop is due to a component (hereinafter also denoted as a “relaxation component”) other than the ohmic component which is contained in the internal resistance of battery 12. This relaxation component causes battery voltage VB to drop gradually over, for example, about 30 minutes to 1 hour after the stop of charging. Battery voltage VB eventually converges to a voltage value corresponding to the battery capacity. The time period from the stop of charging of battery 12 to converge of battery voltage VB varies from battery to battery.

As battery 12 deteriorates, the internal resistance of battery 12 gradually increases. In particular, the relaxation component of the internal resistance is considered to increase with deterioration. In addition, as battery 12 deteriorates, the voltage and battery capacity thereof decrease. Therefore, as battery 12 deteriorates, the amount of drop in battery voltage VB after the stop of charging becomes larger.

Based on signal VBf output from voltage detector 24, deterioration diagnosis unit 38 measures battery voltage VB at a time t2 after a lapse of a predetermined time period T1 from time t1 at which charging of battery 12 was stopped. In the following description, the measured value of battery voltage VB at time t2 is denoted as “battery voltage VB1”. Predetermined time period T1 is set to, for example, about 30 minutes to 1 hour. Predetermined time period T1 is set to include a time period for battery voltage VB to relax after the stop of charging of battery 12. Thus, the capacity deterioration of battery 12 can be deteriorated with reduced influence of relaxation of battery voltage VB after the stop of charging.

Deterioration diagnosis unit 38 determines whether battery 12 has deteriorated based on battery voltage VB1. Specifically, deterioration diagnosis unit 38 compares battery voltage VB1 with a predetermined threshold voltage Vth and generates a deterioration detection signal φ27 based on a comparison result. When VB1≥Vth, it is determined that battery 12 has not deteriorated, and deterioration detection signal φ27 is set to the “L.” level. When VB1<Vth, it is determined that battery 12 has deteriorated, and deterioration detection signal φ27 is set to the “H” level. Next, the discharging command is temporarily set to the “H” level in a predetermined time period T2 from a time t3 to a time t4, which is after time t2. Predetermined time period T2 is set to, for example, about several tens of milliseconds to one second.

Charging/discharging control unit 36 operates bidirectional chopper 7 in response to discharging command at the “H” level to perform pulse discharging of battery 12. Charging/discharging control unit 36 controls bidirectional chopper 7 such that DC voltage VD of DC line 5 becomes equal to reference DC voltage VDR in predetermined time period T2. During execution of pulse discharging, battery 12 is discharged at a constant current value.

During execution of pulse discharging, battery voltage VB drops. Specifically, immediately after the start of pulse discharging, battery voltage VB drops abruptly due to the internal resistance of battery 12, and then, drops gradually. Deterioration diagnosis unit 38 measures the minimum voltage of battery 12 during execution of pulse discharging based on signal VBf output from voltage detector 24. In the following description, the measured value of the minimum voltage during execution of pulse discharging is denoted as “battery voltage VB2”. Battery voltage VB2 corresponds to battery voltage VB at time t4 at which the pulse discharging is stopped.

As pulse discharging is stopped at time t4, battery voltage VB begins to rise. Immediately after the stop of pulse discharging, battery voltage VB rises abruptly. This voltage rise is caused by the current during discharging and the internal resistance of battery 12.

Based on signal VBf output from voltage detector 24, deterioration diagnosis unit 38 measures battery voltage VB at a time t5 after a lapse of a predetermined time period T3 from time t4 at which the pulse discharging was stopped. Predetermined time period T3 is set to, for example, about several tens of milliseconds to one second. In the following description, the measured value of battery voltage VB at time t5 is denoted as “battery voltage VB3”.

Next, deterioration diagnosis unit 38 calculates a direct current resistance (DCR) of battery 12 using battery voltage VB2, which is the minimum voltage during pulse discharging, battery voltage VB3 immediately after pulse discharging, and a current value I during pulse discharging. The DCR is calculated by the following Equation (1). The DCR includes the ohmic component and the relaxation component described above.

$$DCR = ( VB 3 - VB 2 ) / I \qquad ( 1 )$$

Deterioration diagnosis unit 38 determines the deteriorated state of battery 12 based on the calculated DCR. In an aspect, deterioration diagnosis unit 38 determines the progress of deterioration of battery 12 by comparing the DCR calculated in the past deterioration diagnosis mode with the DCR calculated in the current deterioration diagnosis mode. For example, when the amount of increase in DCR from the previous deterioration diagnosis mode is greater than the amount of increase in DCR in the past, it can be determined that the progression rate of deterioration of battery 12 is on the rise. In this case, the life of battery 12 is expected to be shorter than assumed. Contrastingly, when it is determined that the progression rate of deterioration of battery 12 is slow from the amount of increase in DCR, the life of battery 12 is expected to be longer than assumed. Deterioration diagnosis unit 38 generates state signal φ28 based on these determination results.

Deterioration diagnosis unit 38 also determines whether battery 12 has deteriorated based on the calculated DCR. Specifically, deterioration diagnosis unit 38 compares the calculated DCR with a threshold DCRth provided from threshold generation unit 42, and generates deterioration detection signal φ27 based on a comparison result. When DCR≤DCRth, it is determined that battery 12 has not deteriorated, and deterioration detection signal φ27 is set to the “L” level. When DCR>DCRth, it is determined that battery 12 has deteriorated, and deterioration detection signal ¢27 is set to the “H” level.

When the execution of the deterioration diagnosis mode is completed (time t6), deterioration diagnosis unit 38 sets reset signal RST to the “H” level for a predetermined time period to reset timer 26, and performs the normal mode again. The charging command is then set to the “H” level.

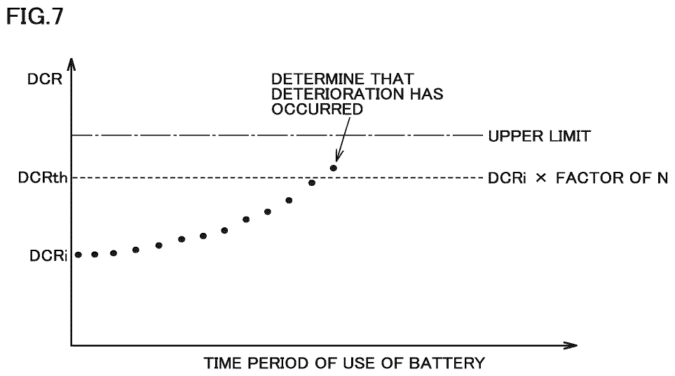

Returning to FIG. 5, deterioration diagnosis unit 38 outputs the generated state signal φ28 and deterioration detection signal φ27 to output unit 27. Output unit 27 presents information on the deteriorated state of battery 12 to the user of uninterruptible power supply device 100 based on state signal φ28. For example, output unit 27 generates a graph (see FIG. 7) indicating a time transition of the calculated value of the DCR and displays the time shift on the image display unit of operation unit 9 (or the display of the external device). When deterioration detection signal φ27 is at the “H” level, output unit 27 notifies the user of uninterruptible power supply device 100 that battery 12 has deteriorated using sound, light, an image, or the like.

Further, deterioration diagnosis unit 38 stores the calculated DCR in storage unit 40. Storage unit 40 stores the time period of use of battery 12 and the calculated value of the DCR in association with each other. FIG. 7 shows an example relationship between the time period of use of battery 12 and the DCR. The horizontal axis of FIG. 7 shows the time period of use of battery 12 replaced with a new one, and the vertical axis of FIG. 7 shows the DCR of battery 12.

In FIG. 7, the DCR of battery 12 calculated each time the deterioration diagnostic mode is performed is plotted. As shown in FIG. 7, the DCR increases as battery 12 is used for a longer time period. In the example in FIG. 7, the amount of increase in DCR relative to the cycle in which the deterioration diagnosis mode is performed increases as the time period of use becomes longer.

Returning to FIG. 5, threshold generation unit 42 sets threshold DCRth. In one aspect, threshold generation unit 42 can set threshold DCRth by amplifying the reference value (e.g., design value), which is predetermined for battery 12, by a factor of M, where M is a value greater than 1. By setting threshold DCRth using the reference value of the DCR as described above, the deterioration of battery 12 can be determined from the amount of increase (relative ratio) of DCR relative to the reference value.

In another aspect, threshold generation unit 42 can set threshold DCRth based on the relationship (the graph in FIG. 7) between the time period of use of battery 12 and the DCR stored in storage unit 40. Specifically, threshold generation unit 42 sets threshold DCRth by amplifying the value of the DCR at the early stage of use of battery 12 (corresponding to DCRi in FIG. 7) by a factor of N (DCRth=DCRi×N), where N is a value greater than 1.

As threshold DCRth is set using DCRi at the early stage of use of battery 12 as described above, deterioration of battery 12 can be determined from the amount of increase (relative ratio) in DCR relative to DCRi. In the case of a battery with a small DCRi, the calculated value of the DCR does not reach a value obtained by amplifying the above-mentioned reference value by the factor of M, but the progression rate of deterioration of battery 12 may be on the rise due to some abnormality. By setting threshold DCRth using DCRi, an abnormality that accelerates the progression of battery deterioration at an early stage can be detected regardless of an individual variability in battery.

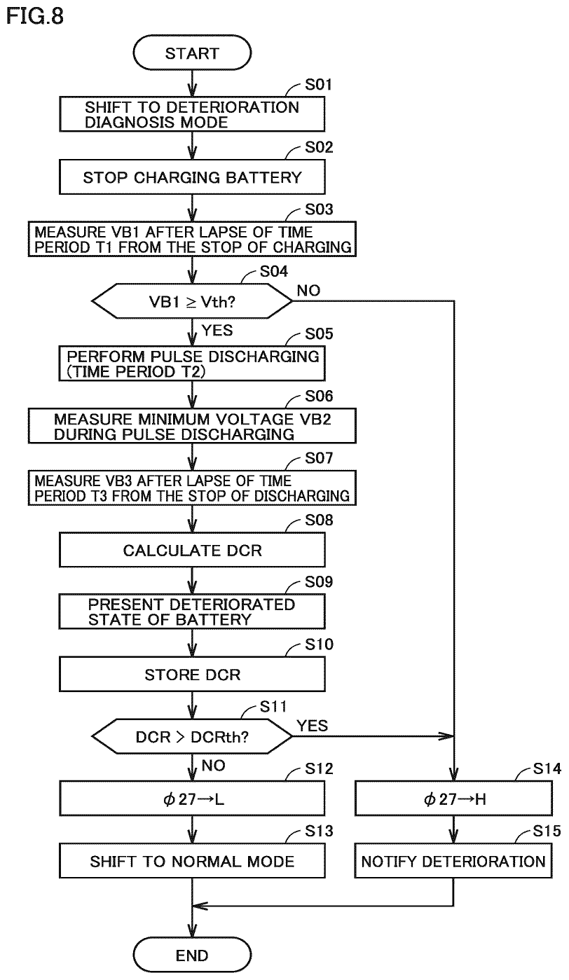

FIG. 8 is a flowchart showing a flow of the deterioration diagnosis process for battery 12 according to Embodiment 1.

As shown in FIG. 8, in step (hereinafter simply denoted as “S”) 01, controller 10 shifts to the deterioration diagnosis mode in response to measured time period TD of timer 26 exceeding predetermined time period Tc during execution of the normal mode.

In the deterioration diagnosis mode, in S02, controller 10 first stops charging of battery 12 by stopping the operation of bidirectional chopper 7. As shown in FIG. 6, battery voltage VB drops as charging of battery 12 was stopped.

In S03, controller 10 measures battery voltage VB1 at the time (time t2 in FIG. 6) after a lapse of predetermined time period T1 from the time (time t1 in FIG. 6) at which charging of battery 12 was stopped, based on signal TDf output from timer 26 and signal VBf output from voltage detector 24.

In S04, controller 10 compares battery voltage VB1 with threshold voltage Vth. When VB1<Vth (when determination is NO in S04), in S14, controller 10 determines that battery 12 has deteriorated and outputs deterioration detection signal φ27 at the “H” level to output unit 27. In S14, output unit 27 notifies the user of uninterruptible power supply device 100 that battery 12 has deteriorated using sound, light, an image, or the like.

Contrastingly, when VB1>Vth (when determination is YES in S04), in S05, controller 10 performs pulse discharging of battery 12 for predetermined time period T2 based on signal TDf output from timer 26. In S05, controller 10 discharges battery 12 at a constant current value.

During execution of pulse discharging, in S06, controller 10 measures the minimum voltage (battery voltage VB2) of battery 12 based on signal VBf output from voltage detector 24.

Subsequently, in S07, controller 10 measures battery voltage VB3 at the time (time t5 in FIG. 6) after a lapse of predetermined time period T3 from the time (time t4 in FIG. 6) when pulse discharging was stopped, based on signal VBf output from voltage detector 24.

In S08, controller 10 calculates the DCR of battery 12 by Equation (1) using battery voltages VB2, VB3 measured in S06, S07 and current value I during pulse discharging.

In S09, controller 10 generates state signal φ28 indicating the deteriorated state of battery 12 based on the DCR calculated in S08 and outputs state signal φ28 to output unit 27. Based on state signal φ28, output unit 27 presents information on the deteriorated state of battery 12 to the user of uninterruptible power supply device 100. In S09, for example, output unit 27 displays the graph (see FIG. 7), which represents the time transition of the calculated value of the DCR calculated every time the deterioration diagnosis mode is performed, on the image display unit of operation unit 9 (or the display of the external device).

In S10, controller 10 stores the DCR calculated in S08 in its internal memory.

In S11, controller 10 compares the DCR calculated in S08 with threshold DCRth. When DCR≤DCRth (when determination is NO in S11), in S12, controller 10 determines that battery 12 has not deteriorated and sets deterioration detection signal φ27 to the “L” level. Subsequently, in S13, controller 10 sets reset signal RST to the “H” level for a predetermined time period to reset timer 26. Reset timer 26 resumes measurement of time period TD from 0 seconds. Consequently, the deterioration diagnosis mode is completed and shifts to the normal mode.

Contrastingly, when DCR>DCRth (when determination is YES in S11), controller 10 determines that battery 12 has deteriorated in S14 and outputs deterioration detection signal 27 at the “H” level to output unit 27. In S15, output unit 27 notifies the user of uninterruptible power supply device 100 that battery 12 has deteriorated.

### <Effects>

As described above, in Embodiment 1, the deteriorated state of battery 12 is diagnosed based on battery voltage VB1 at the time after a lapse of predetermined time period T1 from the stop of charging of battery 12. This enables deterioration diagnosis of battery 12 without test discharging of battery 12. Also, by setting predetermined time period T1 to include the time period (e.g., about 30 minutes to 1 hour) in which battery voltage VB relaxes after the stop of charging of battery 12, the capacity deterioration of battery 12 can be accurately diagnosed with reduced influence of relaxation of battery voltage VB after the stop of charging.

In Embodiment 1, pulse discharging is performed after a lapse of predetermined time period T1 from the stop of charging of battery 12, and the DCR of battery 12 is calculated from minimum voltage VB2 during pulse discharging and battery voltage VB3 immediately after pulse discharging.

Herein, the DCR of battery 12 can also be calculated based on battery voltage VB1 before start of pulse discharging and minimum voltage VB2 during pulse discharging. However, since battery voltage VB1 includes the influence of relaxation of battery voltage VB after the stop of charging in no small amounts, the accuracy of the DCR may decrease. Contrastingly, in Embodiment 1, by calculating the DCR based on minimum voltage VB2 during pulse discharging and battery voltage VB3 immediately after pulse discharging, the DCR can be calculated accurately with reduced influence of relaxation of battery voltage VB.

When predetermined time period T1 is set to a sufficiently long time period in consideration of the relaxation characteristic of battery voltage VB, the influence of relaxation included in battery voltage VB1 at the time after a lapse of predetermined time period T1 becomes smaller. In such a case, a configuration may be made such that the DCR is calculated based on battery voltage VB1 and minimum voltage VB2 during pulse discharging.

Further, threshold DCRth, which is compared with the calculated DCR, can be set using DCRi at the early stage of use of battery 12, to thereby detect an abnormality, which causes the battery to deteriorate faster, at an early stage regardless of an individual difference in battery.

### Embodiment 2

In Embodiment 1, pulse discharging is performed during execution of the deterioration diagnosis mode, and the DCR of battery 12 is calculated based on minimum voltage VB2 during pulse discharging, battery voltage VB3 immediately after pulse discharging, and the current value during pulse discharging. However, pulse discharging may not be performed at a constant current when uninterruptible power supply device 100 is under light load. Embodiment 2 aims to solve such a concern.

Uninterruptible power supply device 100 according to Embodiment 2 is identical to uninterruptible power supply device 100 according to Embodiment 1 in configuration and operation, except for the process in the deterioration diagnosis mode described below.

### <Deterioration Diagnosis Process>

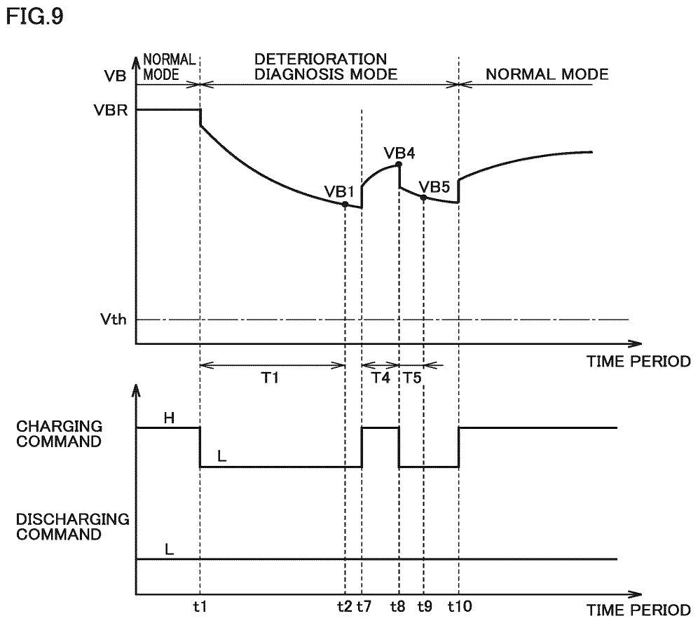

FIG. 9 is a diagram for illustrating the deterioration diagnosis process in deterioration diagnosis unit 38 according to Embodiment 2, which is compared with FIG. 6. FIG. 9 shows the waveform of battery voltage VB indicated by signal VBf output from voltage detector 24 and the waveforms of the charging command and the discharging command generated by command generation unit 32. The deterioration diagnosis process shown in FIG. 9 is different from the deterioration diagnosis process shown in FIG. 6 in that pulse discharging of battery 12 is replaced by pulse charging.

Specifically, the discharging command is maintained at the “L” level during execution of the deterioration diagnosis mode. In a predetermined time period T4 from a time t7 to a time t8, which is after time t2, when predetermined time period T1 has elapsed from time t1 at which charging of battery 12 was stopped, the discharging command is temporarily set to the “H” level. Predetermined time period T4 is set to, for example, about one second.

Charging/discharging control unit 36 operates bidirectional chopper 7 in response to charging command at the “H” level to perform pulse charging of battery 12. Charging/discharging control unit 36 controls bidirectional chopper 7 such that battery voltage VB becomes equal to reference DC voltage VBR in predetermined time period T4. During execution of pulse charging, battery 12 is charged at a constant current value.

During execution of pulse charging, battery voltage VB rises. Specifically, immediately after the start of pulse charging, battery voltage VB rises abruptly due to the internal resistance of battery 12, and then rises gradually. Deterioration diagnosis unit 38 measures the maximum voltage of battery 12 during execution of pulse charging based on signal VBf output from voltage detector 24. In the following description, the measured value of the maximum voltage during execution of pulse charging is denoted as “battery voltage VB4”. Battery voltage VB4 corresponds to battery voltage VB at time t8 at which pulse charging is stopped.

Battery voltage VB begins to drop as pulse charging is stopped at time t8. Immediately after the stop of pulse charging, battery voltage VB drops abruptly. This voltage drop is caused by the current during charging and the internal resistance of battery 12. Thereafter, battery voltage VB drops gradually.

Based on signal VBf output from voltage detector 24, deterioration diagnosis unit 38 measures battery voltage VB at a time t9 after a lapse of a predetermined time period T5 from time t8 at which pulse charging was stopped. Predetermined time period T5 is set to, for example, about several tens of milliseconds to one second. In the following description, the measured value of battery voltage VB at time t9 is denoted as “battery voltage VB5”.

Next, deterioration diagnosis unit 38 calculates the DCR of battery 12 using battery voltage VB4, which is the maximum voltage during pulse charging, battery voltage VB5 immediately after pulse charging, and current value I during pulse charging. The DCR is calculated by the following Equation (2).

$$DCR = ( VB 4 - VB 5 ) / I \qquad ( 2 )$$

Deterioration diagnosis unit 38 determines the deteriorated state of battery 12 based on the calculated DCR. As described in Embodiment 1, deterioration diagnosis unit 38 determines the progress of deterioration of battery 12 by comparing, for example, the DCR calculated in the past deterioration diagnosis mode and the DCR calculated in the current deterioration diagnosis mode. Specifically, deterioration diagnosis unit 38 determines the progress rate of deterioration of battery 12 based on the amount of increase in DCR relative to the cycle in which the deterioration diagnosis mode is performed, and generates state signal φ28 from a determination result.

Deterioration diagnosis unit 38 also determines whether battery 12 has deteriorated based on the calculated DCR. Specifically, deterioration diagnosis unit 38 compares the calculated DCR with threshold DCRth provided from threshold generation unit 42, and generates deterioration detection signal φ27 based on a comparison result. When DCR≤DRth, it is determined that battery 12 has not deteriorated, and deterioration detection signal 627 is set to the “L” level. When DCR>DCRth, it is determined that battery 12 has deteriorated, and deterioration detection signal φ27 is set to the “H” level.

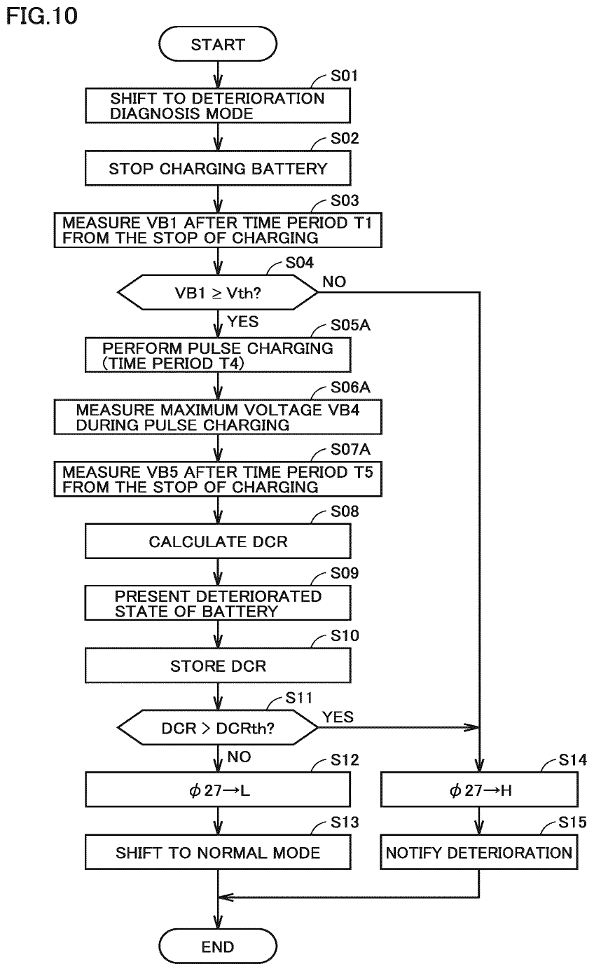

FIG. 10 is a flowchart showing a flow of the deterioration diagnosis process for battery 12 according to Embodiment 2. The flowchart shown in FIG. 10 is obtained by replacing S05 to S07 in the flowchart shown in FIG. 8 with S05A to S07A.

As shown in FIG. 10, when VB1≥Vth in S04 (when determination is YES in S04) as in FIG. 8, in S05A, controller 10 performs pulse charging of battery 12 for predetermined time period T4 based on signal TDf output from timer 26. In S05A, controller 10 charges battery 12 at a constant current value.

During execution of pulse charging, in S06A, controller 10 measures the maximum voltage (battery voltage VB4) of battery 12 based on signal VBf output from voltage detector 24.

Subsequently, in S07A, controller 10 measures battery voltage VB5 at the time (time t9 in FIG. 9) after a lapse of predetermined time period T5 from the time (time t8 in FIG. 9) when pulse charging was stopped, based on signal VBf output from voltage detector 24.

In S08, controller 10 calculates the DCR of battery 12 by Equation (2) using battery voltages VB4, VB5 measured in S06A, S07A and current value I during pulse charging. Controller 10 performs the same processes of S09 to S15 as in FIG. 8 using the calculated DCR.

### <Effects>

According to Embodiment 2, the same effects as those of Embodiment 1 can be obtained. Further, the DCR of battery 12 can be calculated by performing pulse charging of battery 12 also when uninterruptible power supply device 100 is under light load.

Also in Embodiment 2, the DCR of battery 12 is calculated from maximum voltage VB4 during pulse charging and battery voltage VB5 immediately after pulse charging, and thus, compared with the case where the DCR is calculated based on battery voltage VB1 before the start of pulse charging and maximum voltage VB4 during pulse charging, the DCR can be calculated more accurately with reduced influence of relaxation of battery voltage VB.

However, a configuration may be made such that when predetermined time period T1 is set to a sufficiently long time period, the DCR is calculated based on battery voltage VB1 and maximum voltage VB4 during pulse charging, because the influence of relaxation included in battery voltage VB1 at the time at which predetermined time period T1 has elapsed becomes smaller.

### Embodiment 3

In Embodiments 1 and 2, pulse discharging (or pulse charging) is performed during execution of the deterioration diagnosis mode, and the DCR of battery 12 is calculated based on the amount of change in battery voltage VB immediately after pulse discharging (or pulse charging) and the current value during pulse discharging (or pulse charging). In Embodiment 3, depending on the magnitude of the load current, either pulse discharging or pulse charging is performed during execution of the deterioration diagnosis mode to calculate the DCR of battery 12.

Uninterruptible power supply device 100 according to Embodiment 3 is identical to uninterruptible power supply device 100 according to Embodiment 1 in configuration and operation, except for the process in the deterioration diagnosis mode described below.

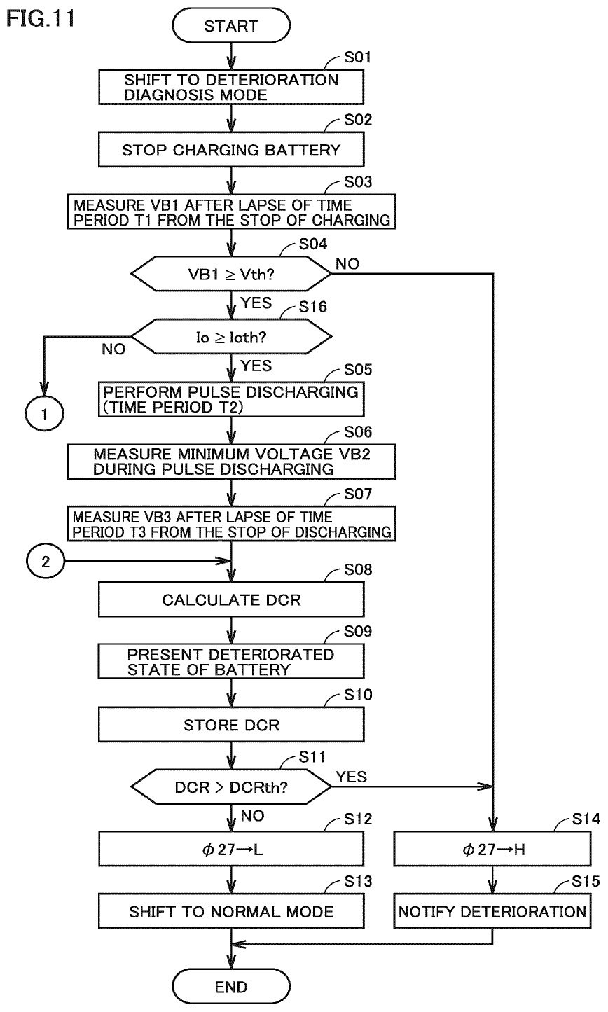

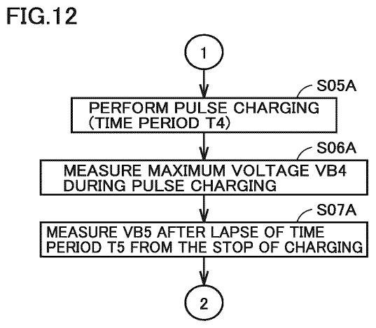

FIGS. 11 and 12 are flowcharts showing a flow of the deterioration diagnosis process for battery 12 according to Embodiment 3. The flowchart shown in FIG. 11 is obtained by adding the process of S16 to the flowchart shown in FIG. 8. The flowchart shown in FIG. 12 is obtained by extracting the processes of S05A to S07A of the flowchart shown in FIG. 10.

As shown in FIG. 11, when VB1≥Vth in S04 (when determination is YES in S04) as in FIG. 8, controller 10 moves to S16 to compare the magnitude between load current Io indicated by signal Iof output from current detector CD3 and a predetermined reference current Ioth. Reference current Ioth is the load current for determining whether uninterruptible power supply device 100 is operating under light load.

When Io≥Ioth (when determination is YES in S16), controller 10 determines that uninterruptible power supply device 100 is not operating under light load. In this case, controller 10 performs pulse discharging of battery 12 and measures battery voltages VB2, VB3 in S05 to S07, as in FIG. 8. Controller 10 then calculates the DCR of battery 12 based on the amount of change in battery voltage VB and the current value during pulse discharging in S08 to S15 as in FIG. 8, and diagnoses the deteriorated state of battery 12 using the calculated DCR.

Contrastingly, when Io≥Ioth (when determination is YES in S16), controller 10 determines that uninterruptible power supply device 100 is operating under light load. In this case, controller 10 performs pulse charging of battery 12 and measures battery voltages VB4, VB5 in S05A to S07A as in FIG. 10. Controller 10 then calculates the DCR of battery 12 based on the amount of change in battery voltage VB and the current value during pulse discharging in S08 to S15 as in FIG. 8, and diagnoses the deteriorated state of battery 12 using the calculated DCR.

### <Effects>

According to Embodiment 3, when the load of uninterruptible power supply device 100 fluctuates, pulse discharging and pulse charging of battery 12 can be performed while being switched according to the magnitude of the load. This enables calculation of the DCR of battery 12 regardless of the magnitude of the load, to thereby diagnose the deteriorated state of battery 12.

### Embodiment 4

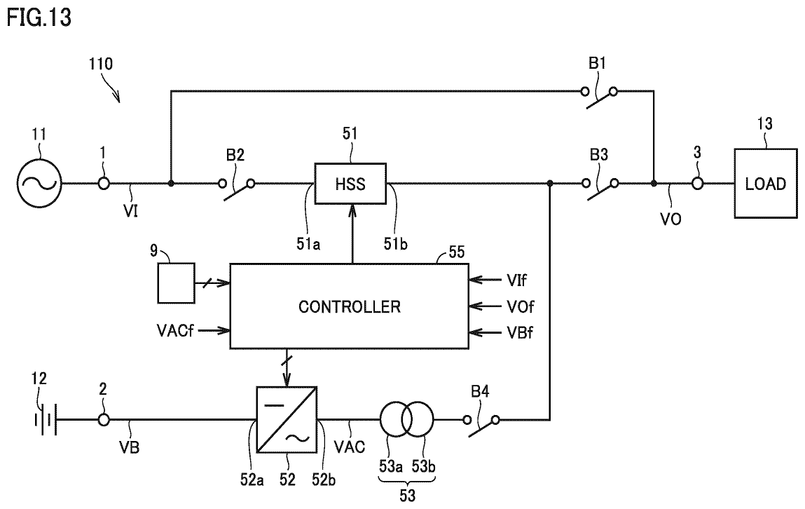

The uninterruptible power supply devices to which the method of diagnosing the deterioration of battery 12 according to the present embodiment is applied can include an uninterruptible power supply device 110 shown in FIG. 13, in addition to uninterruptible power supply device 100 shown in FIG. 1. Uninterruptible power supply device 110 is also referred to as a multiple power compensator.

FIG. 13 is a circuit block diagram showing a configuration of uninterruptible power supply device 110 according to Embodiment 4. Uninterruptible power supply device 110 supplies three-phase AC power to the load, but for simplicity of the drawing and description, only the portions related to one phase are shown in FIG. 13.

As shown in FIG. 13, uninterruptible power supply device 110 includes input terminal 1, output terminal 3, DC terminal 2, breakers B1 to B4, a high speed switch (HSS) 51, a transformer 53, a bidirectional converter 52, and a controller 55. Uninterruptible power supply device 110 is different from uninterruptible power supply device 100 shown in FIG. 1 in that it includes HSS 51, transformer 53, bidirectional converter 52, and controller 55 instead of converter 4, bidirectional chopper 7, inverter 8, and controller 10.

Each of breakers B1 to B4 is, for example, a vacuum circuit breaker (VCB). Breaker B1 is connected between input terminal 1 and output terminal 3. When uninterruptible power supply device 110 is used, breaker B1 is turned off. During maintenance of uninterruptible power supply device 110, breaker B1 is turned on and AC input voltage VI from AC power supply 11 is supplied to load 13 via breaker B1.

Breaker B2 is connected between input terminal 1 and one terminal 51a of HSS 51. Breaker B3 is connected between the other terminal 51b of HSS 51 and output terminal 3. When uninterruptible power supply device 110 is used, breakers B2, B3 are turned on. During maintenance of uninterruptible power supply device 110, breakers B2, B3 are turned off.

HSS 51 is configured of, for example, a semiconductor switching element and is controlled by controller 55. During normal operation of AC power supply 11 (normal mode and deterioration diagnosis mode), HSS 51 is turned on, and AC input voltage VI from AC power supply 11 is supplied to load 13 via breaker B2, HSS 51, and breaker B3. During a power failure of AC power supply 11 (backup mode), HSS 51 is turned off, so that AC power supply 11 and load 13 are electrically disconnected from each other. An instantaneous value of AC voltage VO appearing at the other terminal 51b of HSS 51 is detected by controller 55.

Breaker B4 is connected between the other terminal 51b of HSS 51 and a primary winding 53b of transformer 53. When uninterruptible power supply device 110 is used, breaker B4 is turned on. During maintenance of uninterruptible power supply device 110, breaker B4 is turned off. A secondary winding 53a of transformer 53 is connected to an AC terminal 52b of bidirectional converter 52. Transformer 53 transmits and receives AC power between the other terminal 51b of HSS 51 and AC terminal 52b of bidirectional converter 52. An instantaneous value of an AC voltage VAC appearing at AC terminal 52b of bidirectional converter 52 is detected by controller 55.

A DC terminal 52a of bidirectional converter 52 is connected to DC terminal 2. Bidirectional converter 52 is controlled by controller 55. During normal operation of AC power supply 11 (normal mode), bidirectional converter 52 converts the AC power supplied from AC power supply 11 through breaker B2, HSS 51, breaker B4, and transformer 53 into DC power and stores the DC power in battery 12. During a power failure of AC power supply 11 (backup mode), bidirectional converter 52 converts the DC power of battery 12 into AC power of a commercial frequency and supplies the AC power to load 13 through transformer 53 and breakers B4, B3. Bidirectional converter 52 corresponds to an embodiment of the “power converter”.

Controller 55 controls HSS 51 and bidirectional converter 52 based on AC voltages VI, VO, VAC and battery voltage VB. In other words, when AC power supply 11 is normal (φ25=H), controller 55 performs the normal mode. In the normal mode, controller 55 turns on breakers B2 to B4 and HSS 51. Controller 55 also controls bidirectional converter 52 in synchronization with AC input voltage VI such that battery voltage VB becomes equal to reference DC voltage VBR.

When battery voltage VB reaches reference DC voltage VBR, controller 55 controls bidirectional converter 52 to convert battery voltage VB into AC voltage VAC of a commercial frequency.

When the phase of AC output voltage VAC of bidirectional converter 52 is advanced beyond the phase of AC input voltage VI from AC power supply 11, electric power flows from battery 12 to load 13 through bidirectional converter 52 and battery voltage VB drops. When the phase of AC output voltage VAC is delayed from the phase of AC input voltage VI, electric power flows from AC power supply 11 to battery 12 through bidirectional converter 52 and battery voltage VB rises. Controller 55 controls bidirectional converter 52 to adjust the phase of AC voltage VAC and maintain battery voltage VB at reference DC voltage VBR.

When a power failure occurs in AC power supply 11 (φ25=L), controller 55 performs the backup mode. In the backup mode, controller 55 turns off HSS 51 and controls bidirectional converter 52 such that AC voltage VO becomes equal to reference AC voltage VOR. When AC power supply 11 is restored from a power failure state to a normal state (φ25=H), controller 55 shifts from the backup mode to the normal mode. Controller 55 controls bidirectional converter 52 such that the phase and frequency of AC voltage VO match the phase and frequency of AC input voltage VI, and then turns on HSS 51.

When time period TD indicated by signal TDf output from a timer (not shown) exceeds predetermined time period Tc during execution of the normal mode, controller 55 performs the deterioration diagnosis mode. In the deterioration diagnosis mode, controller 55 diagnoses the deteriorated state of battery 12 while supplying AC power to load 13. Controller 55 controls the operation of bidirectional converter 52 based on signal TDf output from the timer. In an aspect, as shown in FIG. 6, controller 55 stops the operation of bidirectional converter 52 for predetermined time period T1 to stop charging of battery 12 and, based on battery voltage VB1 at the time at which predetermined time period T1 has elapsed from the stop of charging, determines whether battery 12 has deteriorated. Controller 55 further performs pulse discharging of battery 12 and calculates the DCR of battery 12 based on minimum voltage VB2 during pulse discharging and battery voltage VB2 immediately after pulse discharging. Controller 55 determines the deteriorated state of battery 12 based on the calculated DCR, compares the calculated DCT with threshold DCRth, and determines whether battery 12 has deteriorated based on a comparison result.

In another aspect, as shown in FIG. 9, controller 55 stops the operation of bidirectional converter 52 for predetermined time period T1 to stop charging of battery 12 and, based on battery voltage VB1 at the time at which predetermined time period T1 has elapsed from the stop of charging, determines whether battery 12 has deteriorated. Controller 55 further performs pulse charging of battery 12 and calculates the DCR of battery 12 based on maximum voltage VB4 during pulse charging and battery voltage VB5 immediately after pulse charging. Controller 55 determines the deteriorated state of battery 12 based on the calculated DCR, compares the calculated DCR with threshold DCRth, and determines whether battery 12 has deteriorated based on a comparison result. When the execution of the deterioration diagnosis mode is completed, controller 55 sets reset signal RST to the “H” level that is the activation level for a predetermined time period to reset the timer, and performs the normal mode again.

When a power failure occurs in AC power supply 11 during execution of the deterioration diagnosis mode (φ25=L), controller 55 performs the backup mode. In response to the interruption of the execution of the deterioration diagnosis mode, controller 55 sets reset signal RST to the “H” level that is the activation level for a predetermined time period to reset the timer.

### <Effects>

The same effects as those of Embodiment 1 can be obtained also in Embodiment 4. Also in Embodiment 4, a configuration may be made such that when the load of uninterruptible power supply device 110 fluctuates, pulse discharging and pulse charging of battery 12 are performed while being switched according to the magnitude of the load. This enables calculation of the DCR of battery 12 regardless of the magnitude of the load to diagnose the deteriorated state of battery 12.

### Other Configuration Examples

Although Embodiments 1 to 4 above have described the configurations for diagnosing the deteriorated state of a battery used in an uninterruptible power supply device, the deterioration diagnosis method according to the present embodiment can also be applied to a configuration for diagnosing the deteriorated state of each of a plurality of battery modules that constitute a battery. For example, the voltage between the terminals of each battery module can be measured at a time at which a predetermined time period has elapsed from the stop of charging of the battery, and the deteriorated state of the battery module can be diagnosed based on the measured value of this voltage between the terminals. By calculating the DCR of each battery module from the amount of change in the voltage between the terminals of the battery module immediately after pulse discharging or pulse charging of the battery, the deteriorated state of the battery module can be determined based on the calculated value of the DCR.

Further, the deterioration diagnosis method according to the present embodiment can also be applied to a configuration for diagnosing the deteriorated state of each of a plurality of battery cells constituting a battery module. In an aspect, the voltage between the terminals of each battery cell can be measured at the time at which a predetermined time period has elapsed from the stop of charging of the battery, and the deteriorated state of this battery cell can be diagnosed based on the measured value of the voltage between the terminals. Also, by calculating the DCR of each battery cell from the amount of change in the voltage between the terminals of the battery cell immediately after pulse discharging or pulse charging of the battery, the deteriorated state of the battery cell can be determined based on the calculated value of the DCR.

It should be understood that the embodiments disclosed herein are illustrative and non-restrictive in every respect. The present disclosure is defined by the scope of the claims, rather than the description above, and is intended to include any modifications within the meaning and scope equivalent to the scope of the claims.

### REFERENCE SIGNS LIST

1 input terminal; 2 DC terminal; 3 output terminal; 4 converter; 5 DC line; 6 capacitor; 7 bidirectional chopper; 8 inverter; 9 operating unit; 10, 55 controller; 11 AC power supply; 12 battery; 13 load; 21 to 24 voltage detector; 25 power failure detector; 26 timer; 27 output unit; 28 control circuit; 30 mode setting unit; 32 command generation unit; 34 power feed control unit; 36 charging/discharging control unit; 38 deterioration diagnosis unit; 40 storage unit; 42 threshold generation unit; 51 HSS; 52 bidirectional converter; 53 transformer; 100, 110 uninterruptible power supply device; 102 CPU; 104 memory; 106 I/O circuit; 108 bus; S1 to S3 switch; CD1 to CD3 current detector; B1 to B4 breaker.

1. An uninterruptible power supply device having a normal mode of supplying a load with electric power supplied from an alternate-current (AC) power supply, a backup mode of supplying the load with electric power stored in a storage battery during a power failure of the AC power supply, and a deterioration diagnosis mode of diagnosing a deteriorated state of the storage battery, the uninterruptible power supply device comprising:
a power converter that performs floating charge of the storage battery with the electric power supplied from the AC power supply in the normal mode, and discharges the storage battery in the backup mode; and
a controller, wherein
the controller periodically shifts to the deterioration diagnosis mode during execution of the normal mode, and
during execution of the deterioration diagnosis mode, the controller
stops charging of the storage battery by stopping an operation of the power converter,
measures a voltage of the storage battery at a first timing after a lapse of a first time period from stopping charging of the storage battery, and
diagnoses the deteriorated state of the storage battery based on a measured value of the voltage of the storage battery at the first timing.

2. The uninterruptible power supply device according to claim 1, wherein the controller further
operates the power converter to perform pulse discharging of the storage battery in a second time period after the first timing,
measures a minimum voltage of the storage battery during the pulse discharging,
measures the voltage of the storage battery at a second timing after a lapse of a third time period from stopping the pulse discharging,
calculates a direct-current (DC) resistance of the storage battery based on the minimum voltage, a measured value of the voltage of the storage battery at the second timing, and a current value during the pulse discharging, and
diagnoses the deteriorated state of the storage battery based on a calculated value of the DC resistance.

3. The uninterruptible power supply device according to claim 1, wherein the controller further
operates the power converter to perform pulse charging of the storage battery in a second time period after the first timing,
measures a maximum voltage of the storage battery during the pulse charging,
measures a voltage of the storage battery at a second timing after a lapse of a third time period from stopping the pulse charging,
calculates a DC resistance of the storage battery based on the maximum voltage, a measured value of the voltage of the storage battery at the second timing, and a current value during the pulse charging, and
diagnoses the deteriorated state of the storage battery based on a calculated value of the DC resistance.

4. The uninterruptible power supply device according to claim 1, wherein when a load current supplied to the load is greater than a reference current determined in advance, the controller further
operates the power converter to perform pulse discharging of the storage battery in a second time period after the first timing,
measures a minimum voltage of the storage battery during the pulse discharging,
measures a voltage of the storage battery at a second timing after a lapse of a third time period from stopping the pulse discharging,
calculates a DC resistance of the storage battery based on the minimum voltage, a measured value of the voltage of the storage battery at the second timing, and a current value during the pulse discharging, and
diagnoses the deteriorated state of the storage battery based on a calculated value of the DC resistance.

5. The uninterruptible power supply device according to claim 4, wherein when the load current is smaller than the reference current, the controller further
operates the power converter to perform pulse charging of the storage battery in a fourth time period after the first timing,
measures a maximum voltage of the storage battery during the pulse charging, measures a voltage of the storage battery at a fourth timing after a lapse of a fifth time period from stopping the pulse charging,
calculates a DC resistance of the storage battery based on the maximum voltage, a measured value of the voltage of the storage battery at the fourth timing, and a current value during the pulse charging, and
diagnoses the deteriorated state of the storage battery based on a calculated value of the DC resistance.

6. The uninterruptible power supply device according to claim 2, wherein
the controller generates a state signal indicating the deteriorated state of the storage battery from a time transition of a calculated value of the DC resistance, the DC resistance being calculated every time the deterioration diagnosis mode is performed, and
the uninterruptible power supply device further comprises an output unit that presents information on the deteriorated state of the storage battery to a user of the uninterruptible power supply device based on the state signal.

7. The uninterruptible power supply device according to claim 2, wherein the controller
stores, in a storage unit, a time period of use of the storage battery and the calculated value of the DC resistance in association with each other,
sets a threshold by amplifying the DC resistance at an early stage of use of the storage battery by a predetermined factor, the DC resistance being stored in the storage unit, and
diagnoses that the storage battery has deteriorated when a calculated value of the DC resistance is greater than the threshold.

8. The uninterruptible power supply device according to claim 1, wherein the controller shifts to the backup mode when a power failure occurs in the AC power supply during execution of the deterioration diagnosis mode.

9. The uninterruptible power supply device according to claim 3, wherein
the controller generates a state signal indicating the deteriorated state of the storage battery from a time transition of a calculated value of the DC resistance, the DC resistance being calculated every time the deterioration diagnosis mode is performed, and
the uninterruptible power supply device further comprises an output unit that presents information on the deteriorated state of the storage battery to a user of the uninterruptible power supply device based on the state signal.

10. The uninterruptible power supply device according to claim 4, wherein
the controller generates a state signal indicating the deteriorated state of the storage battery from a time transition of a calculated value of the DC resistance, the DC resistance being calculated every time the deterioration diagnosis mode is performed, and
the uninterruptible power supply device further comprises an output unit that presents information on the deteriorated state of the storage battery to a user of the uninterruptible power supply device based on the state signal.

11. The uninterruptible power supply device according to claim 5, wherein
the controller generates a state signal indicating the deteriorated state of the storage battery from a time transition of a calculated value of the DC resistance, the DC resistance being calculated every time the deterioration diagnosis mode is performed, and
the uninterruptible power supply device further comprises an output unit that presents information on the deteriorated state of the storage battery to a user of the uninterruptible power supply device based on the state signal.

12. The uninterruptible power supply device according to claim 3, wherein the controller
stores, in a storage unit, a time period of use of the storage battery and the calculated value of the DC resistance in association with each other,
sets a threshold by amplifying the DC resistance at an early stage of use of the storage battery by a predetermined factor, the DC resistance being stored in the storage unit, and
diagnoses that the storage battery has deteriorated when a calculated value of the DC resistance is greater than the threshold.

13. The uninterruptible power supply device according to claim 4, wherein the controller
stores, in a storage unit, a time period of use of the storage battery and the calculated value of the DC resistance in association with each other,
sets a threshold by amplifying the DC resistance at an early stage of use of the storage battery by a predetermined factor, the DC resistance being stored in the storage unit, and
diagnoses that the storage battery has deteriorated when a calculated value of the DC resistance is greater than the threshold.

14. The uninterruptible power supply device according to claim 5, wherein the controller
stores, in a storage unit, a time period of use of the storage battery and the calculated value of the DC resistance in association with each other,
sets a threshold by amplifying the DC resistance at an early stage of use of the storage battery by a predetermined factor, the DC resistance being stored in the storage unit, and
diagnoses that the storage battery has deteriorated when a calculated value of the DC resistance is greater than the threshold.
